(19) United States
(12) Patent Application Publication
(10) Pub. No.: US 2020/0260593 A1
(43) Pub. Date: Aug. 13, 2020

(54) METHOD OF FORMING A SOLDER CONNECTION AND CARRIER WITH A COMPONENT FIXED TO THE CARRIER BY A SOLDER CONNECTION

(71) Applicant: FM Siebdruck Werbung Design GmbH, Waldenbuch (DE)

(72) Inventor: Michael Bayer, Neuhausen (DE)

(21) Appl. No.: 16/739,303

(22) Filed: Jan. 10, 2020

(30) Foreign Application Priority Data
Feb. 8, 2019 (EP) 19156144.8

(51) Int. Cl. H05K 3/34; B23K 1/20; B23K 1/00; H05K 1/18

(52) U.S. Cl. CPC H05K 3/341; B23K 1/20; B23K 2101/42; H05K 3/3494; H05K 1/181; B23K 1/0008

(57) ABSTRACT

A method of forming a solder connection between a carrier and a component includes a) printing an electrically conductive layer containing metal particles on a surface of the carrier by a printing process, b) printing a solder onto the electrically conductive layer by a printing process, c) arranging the component on the carrier so that the component is in direct contact with the solder, and d) melting the solder and then solidifying the solder to form the solder connection, wherein e) prior to printing the solder, the metal particles of the electrically conductive layer are coated with a precious metal coating, and f) a solder mediator agent including a precious metal salt or a precious metal oxide from which a precious metal is released to form the precious metal coating is applied onto the electrically conductive layer by a printing process.

### TECHNICAL FIELD

This disclosure relates to a method of forming a solder connection and a carrier with a component, preferably an electronic component, fixed to the carrier by a solder connection.

### BACKGROUND

Methods of forming solder connections are known. For example, DE 10 2013 218 423 A1 discloses a process of fixing an electronic component to a carrier, in particular to a printed circuit board. For that purpose, a first layer and a second layer are applied onto a surface of the carrier, the first layer containing metal particles and a flux and the second layer containing a solder. The metal particles are applied to form a conductive layer on the carrier. The conductive layer is to be connected to the electronic component with the aid of the solder. The component is brought into direct contact with the layers, followed by a heat treatment in which the metal particles in the first layer sinter and the solder is liquefied. The liquefied solder diffuses from the second layer into cavities in the first layer created during sintering. The flux removes oxides from the surfaces of the metal particles of the first layer, which supports infiltration of the liquid solder into the framework structure of the sintered metal particles. However, the flux has a negative influence on the printability of the first layer. In addition, sintering requires high temperatures depending on the selected metal particles, which in turn greatly limits the choice of the carrier with regard to its temperature resistance.

DE 10 2008 031 004 A1 discloses forming a solder powder using a solid metal stearate. The metal stearate is contained in a binder enclosing a solder material. It is formed from a base metal such as aluminium or manganese. Such a metal stearate is basically suitable for reducing oxide layers on the surfaces of metal particles and thus making a flux superfluous.

DE 10 2016 226 089 A1 discloses a process of forming a solder connection in which a first and a second layer are applied to a carrier, the first layer containing at least one metal stearate in addition to metal particles and the second layer containing a solder. There, too, the metal particles of the first layer are applied to form a conductive layer on the carrier. The carrier and the two layers are then subjected to a heat treatment in which the second layer with the solder is liquefied and penetrates into the structure of the first layer containing the metal particles. The metal stearate serves as a substitute for thixotropic agents contained in common fluxes. Preferably, the metal stearate is an aluminium stearate.

The known methods have disadvantages. Although conductor tracks made of sintered metal particles are very well suited for soldering, many carriers cannot tolerate the temperatures required for sintering. Conductor tracks made of unsintered metal particles such as those printed from low-temperature conductive pastes often contain an organic binder that is difficult to wet with a liquid solder. Instead, the solder dissolves metal particles from the conductor track, which in extreme cases can damage the track.

Printed conductor tracks can also be galvanically reinforced before they are soldered to electronic components. However, such an intermediate wet-chemical step is costly and therefore to be avoided whenever possible.

It could therefore be helpful to provide an improved method of forming a solder connection and allow a purely additive application of the layers required to form the solder connection, in particular by printing, and/or without the need for galvanic reinforcement of printed conductor tracks before soldering. Further, it could be helpful to provide a method of forming a solder connection suitable for a variety of carriers including temperature-sensitive ones.

### SUMMARY

I provide a method of forming a solder connection between a carrier and a component including a) printing an electrically conductive layer containing metal particles on a surface of the carrier by a printing process, b) printing a solder onto the electrically conductive layer by a printing process, c) arranging the component on the carrier so that the component is in direct contact with the solder, and d) melting the solder and then solidifying the solder to form the solder connection, wherein e) prior to printing the solder, the metal particles of the electrically conductive layer are coated with a precious metal coating, and f) a solder mediator agent including a precious metal salt or a precious metal oxide from which a precious metal is released to form the precious metal coating is applied onto the electrically conductive layer by a printing process.

I also provide a carrier having at least one conductor track on one of its surfaces, including a component fixed to the carrier by a solder connection having been formed according to the method of forming a solder connection between a carrier and a component including a) printing an electrically conductive layer containing metal particles on a surface of the carrier by a printing process, b) printing a solder onto the electrically conductive layer by a printing process, c) arranging the component on the carrier so that the component is in direct contact with the solder, and d) melting the solder and then solidifying the solder to form the solder connection, wherein e) prior to printing the solder, the metal particles of the electrically conductive layer are coated with a precious metal coating, and f) a solder mediator agent including a precious metal salt or a precious metal oxide from which a precious metal is released to form the precious metal coating is applied onto the electrically conductive layer by a printing process, wherein the solder connection includes traces of the precious metal salt or the precious metal oxide used in the method.

### BRIEF DESCRIPTION OF THE DRAWINGS

FIGS. 1A-1G schematically illustrate the method.

### DETAILED DESCRIPTION

The method of forming a solder connection between a carrier and a component, in particular an electronic component comprises the steps a) to d):

a) an electrically conductive layer containing metal particles is printed on a surface of the carrier by a printing process,
b) a solder is printed onto this electrically conductive layer by a printing process,
c) the component is arranged on the carrier so that the component is in direct contact with the solder, and
d) the solder is melted and then solidifies to form the solder connection.

In particular, the method is characterized in that

e) prior to the printing of the solder, the metal particles of the electrically conductive layer are coated with a precious metal coating and for this purpose, and
f) a solder mediator agent comprising a precious metal salt or a precious metal oxide from which a precious metal is released to form the precious metal coating is applied onto the electrically conductive layer by a printing process.

Surprisingly, it turned out that stable and reliable solder connections can be obtained by using the solder mediator agent containing the precious metal salt or the precious metal oxide. This also applies if the electrically conductive layer is printed from a low-temperature conductive paste and the metal particles are not sintered in an intermediate step before the solder is melted. According to the method, stable solder connections between electronic components and a carrier can be formed without the need for intermediate wet chemical steps like the galvanic reinforcements mentioned above. Application of the required components (the electrically conductive layer and the solder) can be accomplished by additive steps only, especially by a printing process.

Screen printing is particularly suitable as a printing method. This applies to printing the electrically conductive layer as well as to printing the solder mediator agent and the solder. Screen printing is a printing process in which printing pastes are pressed (preferably by a squeegee) through a fine-mesh fabric onto a substrate. The mesh openings of the fabric are made impermeable at those parts of the fabric where, in dependency of the structure to be printed, no paste is to be applied onto the substrate. In the remaining areas, however, the printing paste should be able to penetrate the mesh openings. To avoid clogging of the mesh openings, solid particles contained in the printing paste should not exceed a certain maximum size, which should be less than the mesh opening size.

Preferably, the precious metal salt is characterized by at least one of a) to f):

a) the precious metal salt is a salt that decomposes at a temperature <250° C., preferably <200° C.,
b) the precious metal salt is selected from the group consisting of silver salt, copper salt, gold salt, nickel salt, platinum salt and palladium salt,
c) the precious metal salt is a salt of a carboxylic acid, especially a silver salt of a carboxylic acid,
d) the carboxylic acid is a C₆ to C₁₅ carboxylic acid, i.e., a carboxylic acid comprising between 6 and 15 carbon atoms,
e) the precious metal salt is a neo-decanoate, and
f) the precious metal salt is silver (I) neodecanoate (IUPAC: silver-3,3,5,5-tetramethylhexanoate).

Preferably at least b) and c), particularly preferably at least b) to d), in particular at least a) to d), are realized in combination with each other.

Particularly preferably, the precious metal salt used is a silver salt of a carboxylic acid, especially the silver (I) neodecanoate.

If the solder mediator agent comprises a precious metal oxide, this precious metal oxide is preferably chosen from silver oxide and copper oxide.

Release of the precious metal from the precious metal salt or the precious metal oxide can be initiated in different ways. Further preferably, the method is characterized by at least one of a) to c):

a) the precious metal salt or the precious metal oxide is heated to release the precious metal, preferably to a temperature of ≤250° C., preferably ≤200° C., in particular to a temperature 120° C. to 250° C., more preferably to a temperature 120° C. to 200° C.,
b) the precious metal salt or the precious metal oxide is irradiated to release the precious metal, especially with UV (ultraviolet) or microwave radiation, and
c) the precious metal salt or the precious metal oxide is brought into contact with a reducing agent to release the precious metal.

Particularly preferably, the process of releasing the precious metal comprises a), whereby it may be preferred to heat the precious metal salt in the presence of a reducing agent and so to combine a) with c). The metal particles of the electrically conductive layer are therefore preferably coated with the precious metal coating in the course of a heat treatment before the solder is subsequently printed onto the electrically conductive layer and melted.

Heating can be done in an oven, for example. If necessary, heating can take place in a reducing atmosphere, for example, in a hydrogen or carbon monoxide atmosphere. The hydrogen and carbon monoxide can then act as a reducing agent.

It can also be preferred to carry out the heating under a protective gas, for example, under argon.

To release silver from silver oxide, a combination of a reducing agent and heating is usually preferred.

Preferably, the solder mediator agent used in the process is characterized by at least one of a) to c):

a) the solder mediator agent has a silver content of 10 to 25 weight percent,
b) the solder mediator agent contains a solvent in addition to the precious metal salt, and
c) the solder mediator agent contains the reducing agent in addition to the precious metal salt.

Preferably, at least b) and c) are realized in combination with each other.

The solvent is preferably added to convert the solder mediator agent into a printable state. The solvent may be, for example, water, an alcohol such as isopropanol or ethylene glycol, or an alcoholic solution such as a water/ethylene glycol mixture. Acetone, ethyl acetate, tetrahydrofuran or acetic acid can also be used.

As reducing agents, for example, ascorbic acid, citric acid, glucose, glyceraldehyde or ammonium formate can be used.

Furthermore, the solder mediator agent can contain a complexing agent as an additive that can form a complex with precious metal ions released from the precious metal salt or the precious metal oxide. An example of this is ammonia.

Preferably, the solder used in the method is characterized by at least one of a) to d): a) the solder comprises or is a low temperature solder,

b) the solder melts at a temperature ≤250° C., preferably ≤200° C.,
c) the solder comprises an alloy comprising or consisting of the elements Sn, Bi and Ag (tin, bismuth and silver), and
d) the solder is processed as a paste or as a suspension.

Preferably, at least a) and b), particularly preferably a), b) and d), more preferably a) to d), are realized in combination with each other.

Melting the solder is particularly preferably effected in the course of a reflow soldering process. The term reflow soldering describes a soldering process commonly used in electrical engineering, in which the solder is applied to the electrically conductive layer to be soldered in the form of a paste. On this paste, which is usually sticky, the components to be soldered can be fixed. In a further step the solder is melted. The soldered connection to the component is formed during the subsequent cooling when the molten solder solidifies.

I provide the use of comparatively temperature-sensitive carriers like carriers made of plastic, for example, plastic films. Preferably, the carrier has at least one of a) to c):

a) the surface of the carrier has electrically insulating properties,
b) the surface of the carrier is made of a plastic, a ceramic material or a metal oxide, and
c) the surface of the carrier is formed by a printing process.

The term “plastic” also includes paint layers based on a polymer binder, for example, polyurethane- or epoxy-based paint layers. These paint layers can also contain particles of the ceramic material or the metal oxide.

Particularly preferably, the carrier is a metal foil, for example, an aluminium foil having a surface formed by an electrically insulating layer applied to the foil by a printing process, for example, a layer of ceramic particles or a layer of paint, or a paint layer comprising the ceramic particles.

Preferably, the carrier has a maximum length of 1650 mm, in particular a length of 100 mm to 1650 mm, and a maximum width of 1000 mm, in particular a width of 100 mm to 1000 mm. It is particularly preferred that the carrier has a rectangular form.

The electrically conductive layer produced in the context of the method is preferably characterized by at least one of a) to e):

a) at least one conductor track is applied to the carrier as the electrically conductive layer,
b) the metal particles of the electrically conductive layer, in particular of the at least one conductor track, are chosen from particles of silver, copper, gold, palladium, platinum or nickel or of an alloy of these metals, or are a mixture of such particles,
c) the layer containing the metal particles is formed from a paste or from a suspension containing the metal particles,
d) the paste or the suspension contains an organic binder in addition to the metal particles, and
e) the electrically conductive layer containing the metal particles is formed by a printing process.

The electrically conductive layer, preferably the at least one conductor track, is particularly preferred formed of silver particles.

The above mentioned reducing agent does not necessarily have to be part of the solder mediator agent when it is needed. In some preferred forms it is also possible to add the reducing agent to a paste from which the electrically conductive layer is printed, or to apply it separately to the electrically conductive layer or the solder mediator agent, preferably again by a printing process.

Surface-mount technology (SMT) is a method of producing electronic circuits in which the components are mounted or placed directly onto the surface of printed circuit boards (PCBs). An electronic device so made is called a surface-mount device (SMD). In industry, SMT has largely replaced the through-hole technology construction method of fitting components with wire leads into holes in the circuit board.

I provide each carrier with a component, in particular an electronic component, fixed to the carrier by a solder connection that has been formed according to the method, wherein the solder connection comprises traces of the precious metal salt or the precious metal oxide used in the method.

The component is preferably an electronic component. Preferably, it is a surface-mounted device (SMD). Particularly preferably, the component is a light-emitting diode (short: LED).

The carrier is preferably a PCB.

I further provide devices with a carrier. If the component is an LED, the device may be a luminaire, for example.

Further features as well as advantages resulting therefrom are shown in the following example and in the drawings. The example described below serves only for explanation and better understanding and is not to be understood as restrictive in any way.

In a step 1A, a 50 μm thick insulating layer 111 with electrically insulating properties is printed on an aluminium foil 110 serving as a carrier. For this purpose, a solder resist can be used, for example, as supplied by Lackwerke Peters GmbH & Co. KG of Kempen, Germany, under the tradename SD 2496 TSW. Such a solder resist usually comprises a curable polymer binder as well as a particulate ceramic filler.

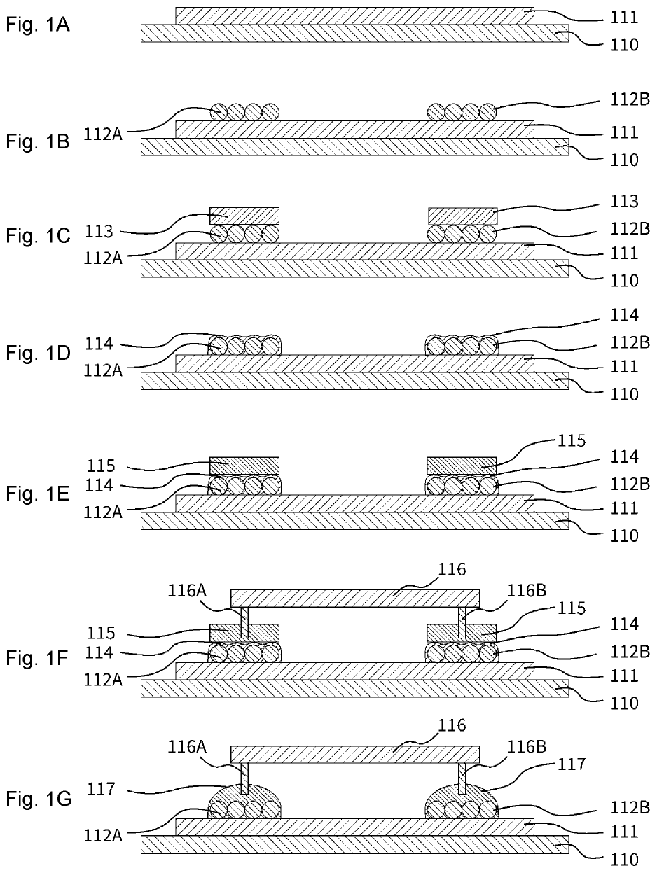

In a step 1B, conductor tracks 112 (112A and 112B) containing silver particles are printed on the insulating layer 111. A paste suitable for this purpose is distributed, for example, by Creative Materials, Inc. of Ayer, Mass. 01432, USA, under the tradename 125-26A/B119-44. The paste comprises, in addition to silver particles with a particle size of <10 μm in a proportion of at least 85%, a 2-component epoxy system as a binder. The silver particles forming tracks 112A and 112B are not shown to scale in FIG. 1 and the choice of the number of silver particles is arbitrary.

In a step 1C, a pasty solder mediator agent 113 comprising silver (I) neodecanoate as a precious metal salt, is printed in areas or sections on the conductor tracks 112A and 112B and thus on the silver particles of the conductor tracks.

Immediately afterwards, in step 1D, the aluminium foil 110 together with the insulating layer 111, the conductor tracks 112A and 112B and the pasty solder mediator agent 113 are heated in an oven at a temperature of 200° C. for a period of 3 to 5 minutes. During this process, metallic silver is released from the precious metal salt and deposits on the surface of the silver particles contained in the silver paste. There it forms the precious metal coating 114.

In step 1E, solder 115 is then printed onto the precious metal coating 114. Suitable is, for example, a pasty low-temperature solder with a melting point <140° C. comprising particles of the composition 42% Sn, 57.6% Bi and 0.4% Ag in a proportion of 90%, whereby the particles have particle sizes of 25 to 45 um. Such a solder is sold, for example, by Alpha Assembly Solutions of Woking, Surrey, GU21 5RW, United Kingdom, under the tradename ALPHA® CVP-520.

In step 1F, an electronic component 116 with its electrical contacts 116A and 116 B is fixed to the low-temperature solder 115. The electronic component can be an LED, for example.

In a step 1G, the low-temperature solder 115 is melted and solidifies to form a soldered connection 117 between the conductor tracks 112A and 112B and the electronic component 116.

1. A method of forming a solder connection between a carrier and a component comprising:
a) printing an electrically conductive layer containing metal particles on a surface of the carrier by a printing process,
b) printing a solder onto the electrically conductive layer by a printing process,
c) arranging the component on the carrier so that the component is in direct contact with the solder, and
d) melting the solder and then solidifying the solder to form the solder connection, wherein
e) prior to printing the solder, the metal particles of the electrically conductive layer are coated with a precious metal coating, and
f) a solder mediator agent comprising a precious metal salt or a precious metal oxide from which a precious metal is released to form the precious metal coating is applied onto the electrically conductive layer by a printing process.

2. The method according to claim 1, where the precious metal salt is characterized by a combination of:
g) the precious metal salt is a salt that decomposes at a temperature ≤200° C., and
h) the precious metal salt is selected from the group consisting of silver salt, copper salt, gold salt, nickel salt, platinum salt and palladium salt.

3. The method according to claim 1, wherein the precious metal salt is characterized by a combination of:
i) the precious metal salt is a salt of a carboxylic acid or a silver salt of a carboxylic acid, and
j) the carboxylic acid is a C₆ to C₁₅ carboxylic acid or a carboxylic acid comprising 6 to 15 carbon atoms.

4. The method according to claim 1, wherein the precious metal salt or the precious metal oxide is heated to release the precious metal to a temperature of 120° C. to 250° C.

5. The method according to claim 1, wherein the precious metal salt or the precious metal oxide is irradiated to release the precious metal with UV (ultraviolet) or microwave radiation.

6. The method according to claim 1, wherein the precious metal salt or the precious metal oxide is brought into contact with a reducing agent to release the precious metal.

7. The method according to claim 1, wherein
the solder mediator agent has a silver content of 10 to 25 weight percent, and
the solder mediator agent contains a solvent in addition to the precious metal salt.

8. The method according to claim 1, wherein the solder mediator agent contains the reducing agent in addition to the precious metal salt.

9. The method according to claim 1, wherein the solder comprises or is a low temperature solder that melts at a temperature <250° C.

10. The method according to claim 1, wherein
the solder comprises an alloy comprising or consisting of the elements Sn, Bi and Ag (tin, bismuth and silver), and
the solder is processed as a paste or as a suspension.

11. The method according to claim 1, wherein
the surface of the carrier has electrically insulating properties,
the surface of the carrier is made of a plastic, a ceramic material or a metal oxide, and
the surface of the carrier is formed by a printing process.

12. The method according to claim 1, wherein
at least one conductor track is applied to the carrier as the electrically conductive layer, and
the metal particles of the electrically conductive layer or the at least one conductor track are chosen from particles of silver, copper, gold, palladium, platinum or nickel or of an alloy of these metals, or are a mixture of the particles.

13. The method according to claim 1, wherein
the electrically conductive layer containing the metal particles is formed from a paste or from a suspension containing the metal particles,
the paste or the suspension contains an organic binder in addition to the metal particles, and
the electrically conductive layer containing the metal particles is formed by a printing process.

14. The method according to claim 1, wherein
the component is surface-mounted device, and
the carrier is a printed circuit board.

15. The method according to claim 1, wherein the component is a light-emitting diode.

16. The method according to claim 1, wherein
the precious metal salt is a neo-decanoate, and
the precious metal salt is a silver salt.

17. A carrier having at least one conductor track on one of its surfaces, comprising a component fixed to the carrier by a solder connection having been formed according to the method of claim 1, wherein the solder connection comprises traces of the precious metal salt or the precious metal oxide used in the method.
